(19) United States
(12) Patent Application Publication
(10) Pub. No.: US 2022/0183197 A1
(43) Pub. Date: Jun. 9, 2022

(54) SYSTEM AND METHODS FOR ASSISTING WITH MANUAL ASSEMBLY AND TESTING OF PRINTED CIRCUIT BOARDS

(71) Applicant: EBOSISTANT LTD., Yoqneam Illit (IL)

(72) Inventor: David Nathan ARLINSKY, Atlit (IL)

(21) Appl. No.: 17/442,419

(22) PCT Filed: Apr. 1, 2020
(86) PCT No.: PCT/IL2020/050398

§ 371 Date: Sep. 23, 2021

Related U.S. Application Data
(60) Provisional application No. 62/827,506, filed on Apr. 1, 2019.

(51) Int. Cl. H05K 13/00; H05K 13/08

(52) U.S. Cl. CPC H05K 13/0053; H05K 13/0812; H05K 13/0015

(57) ABSTRACT

A system and methods are provided for assisting with manual assembly of a printed circuit board (PCB), including a camera, oriented to capture a camera image of some or all of the PCB, and a processor configured to determine according to the camera image, a registration between a physical position of the PCB and a PCB layout; to receive a PCB worklist of tasks to perform on components of the PCB; to determine, according to the registration and the worklist, a position on the PCB at which a task is to be performed; and responsively to generate an overlay image to visually indicate the position on the PCB at which the task is to be performed.

### FIELD OF THE INVENTION

The present invention relates to a system and method for developing, assembling and testing printed circuit boards (PCBs).

### BACKGROUND

During the last few decades, electronic printed circuit boards (PCBs) have continued to decrease in size and to become more populated with tiny electronic components. Many electronic components have become so small that it is difficult to manually locate them on the PCB for assembly or for testing.

During manual PCB assembly and quality control processes, the operator routinely needs to locate specific components on the board, which has become a time-consuming task, resulting in reduced efficiency. Consequently, there is an increased need for a variety of tools and methodologies to simplify the process of component location on PCBs, to enable rapid and efficient debugging and assembling of modern PCBs.

### SUMMARY

Embodiments of the present invention provide a system and methods for developing, assembling and testing printed circuit boards (PCBs), addressing a need for handling small components and boards by indicating the location of any specific part on the PCB. The part indicated is determined either from a computerized worklist, or directly from a circuit schematic. The indication of the part may be performed by projecting a “visual fence” around the part's location (the fence perimeter being a rectangle, oval, circle, etc.).

There is therefore provided, by embodiments of the present invention, a system for assisting with manual assembly of a printed circuit board (PCB), including a camera, oriented to capture a camera image of some or all of the PCB, and a processor (including memory, with instructions executed to configure the processor actions). The processor may be configured to determine, according to the camera image, a registration between a physical position of the PCB and a PCB layout, to receive a PCB worklist of tasks to perform on components of the PCB, to determine, according to the registration and the worklist, a position on the PCB at which a task is to be performed, and responsively to generate an overlay image to visually indicate the position on the PCB at which the task is to be performed.

In some embodiments, the task to be performed is assembly of a component onto the PCB at the given position. The system may further include a projector configured to receive the overlay image and to project the overlay image visually onto the PCB. The system may also further include a magnification video display, and the processor may be further configured to generate a merged image of the overlay image and the camera image and to present the merged image on the magnification video display. The camera image of the merged image presented on the magnification video display may be a real-time, magnified image of a region of the PCB that includes the position of the PCB at which the task may be to be performed. In some embodiments, the camera may be positioned in an optical unit above the PCB, and the magnification video display may be positioned on top of the optical unit to be viewed from above.

The processor may be further configured to identify components of the PCB in the camera image, to correlate the identified components with components in the PCB worklist to determine a component that may be not present on the PCB, and responsively to determine the task to perform. The task to perform may include mounting the component on the PCB.

The overlay image may further include text related to the component, or text of an instruction to perform related to the task.

The processor may be an embedded processor positioned in one or more of a base, a projector arm, or an optical unit of the system.

The camera may include a zoom lens to provide a high resolution zoomed image of a PCB region including the position on the PCB at which the task may be performed.

In further embodiments, the processor may be configured to record a time of completion of the task and responsively determine a statistic of an operator performance. There is further provided, by embodiments of the present invention, a system for assisting in manual printed circuit board (PCB) testing, including a camera, oriented to capture a camera image of some or all of the PCB and a processor, including memory having instructions that when executed perform steps that include: determining a correspondence between the camera image and a schematic of the PCB, responsively receiving a position request identifying a schematic location, responsively determining a physical position on the PCB of said schematic location, and responsively generating an overlay image to visually indicate said physical position on the PCB.

The system may include an interactive display unit, and the processor may be further configured to present a logical circuit schematic on the interactive display unit, from which an operator can select the schematic location.

There is further provided, by embodiments of the present invention, a computer-based method assisting with manual assembly of a printed circuit board (PCB) having one or more processors and a memory, the memory comprising instructions that when executed by the one or more processor cause the processor to implement the method of capturing with a camera a camera image of some or all of the PCB; determining, according to the camera image, a registration between a physical position of the PCB and a PCB layout; receiving a PCB worklist of tasks to perform on components of the PCB; determining, according to the registration and the worklist, a position on the PCB at which a task is to be performed; and responsively generating an overlay image to visually indicate the position on the PCB at which the task is to be performed.

In some embodiments, the overlay image may be a highlighting pattern and wherein indicating the position on the PCB at which the task is to be performed comprises projecting the overlay image towards the PCB to highlight a component on the PCB.

### BRIEF DESCRIPTION OF DRAWINGS

For a better understanding of various embodiments of the invention and to show how the same may be carried into effect, reference will now be made, by way of example, to the accompanying drawings. Structural details of the invention are shown to provide a fundamental understanding of the invention, the description, taken with the drawings, making apparent to those skilled in the art how the several forms of the invention may be embodied in practice. In the figures:

FIG. 1 is a schematic diagram of a system for assisting with manual assembly of a printed circuit board (PCB) comprising: in accordance with an embodiment of the present invention;

FIG. 2 is a schematic diagram of the system, shown projecting a text message, in accordance with an embodiment of the present invention;

FIG. 3 is a schematic diagram of the system, shown indicating a cabling path, in accordance with an embodiment of the present invention;

FIG. 4 is a schematic diagram of an optical unit of the system, in accordance with an embodiment of the present invention;

FIG. 5 is a schematic diagram of the system, shown receiving a memory cartridge, in accordance with an embodiment of the present invention;

FIG. 6 is a schematic diagram of the system, including a video display, in accordance with an embodiment of the present invention;

FIG. 7 is a schematic diagram of the system, including a top-mounted video display, in accordance with an embodiment of the present invention;

FIG. 8 is a schematic diagram of the system, shown indicating a PCB orientation, in accordance with an embodiment of the present invention;

FIG. 9 is a schematic diagram of an interactive system for A system for assisting with manual assembly of a printed circuit board (PCB), in accordance with an embodiment of the present invention; and

FIG. 10 is a flow diagram of a process for assisting with manual assembly of a printed circuit board, in accordance with an embodiment of the present invention.

### DETAILED DESCRIPTION

Embodiments of the present invention provide methods for improving power efficiency of a data center. Illustrative embodiments of the invention are described below. In the interest of clarity, not all features or components of an actual implementation are necessarily described. Embodiments and/or limitations featured in the figures are chosen for convenience or clarity of presentation and are not meant to limit the scope of the invention.

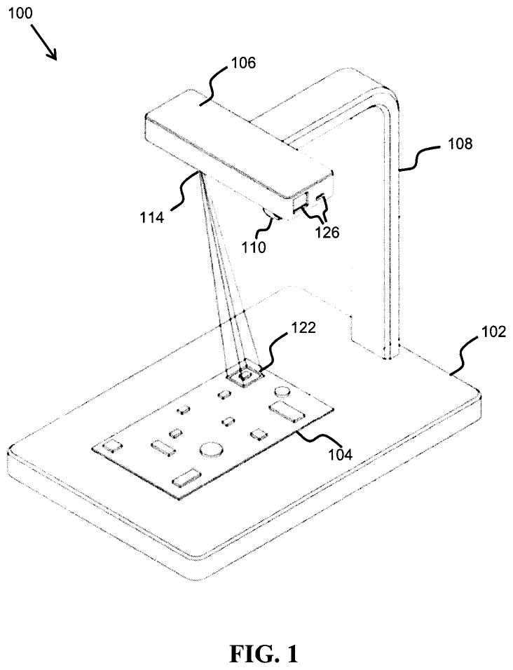

FIG. 1 is a schematic diagram of a system 100 for developing, assembling and/or testing PCBs, in accordance with an embodiment of the present invention. The system provides an operator who is assembling or testing a PCB with a visible pointer to a component or area of the PCB on which the operator is working.

The system includes several basic parts. A base 102 provides a surface on which a PCB 104 (e.g., a “device under test,” or DUT) is placed. Above the base is an optical unit 106, mounted or otherwise affixed to a projection arm 108. The optical unit includes a camera 110 and a projector 114. The camera 110 captures digital images of the PCB 104 and/or the base 102, and provides to a processor a camera feed that may include multiple images or a real time video feed. The projector 114 receives an image or video feed (referred to hereinbelow as a “projection image”), which it then projects onto the PCB and/or the base. The camera and the projector communicate with one or more processors, hereinbelow, the “processor,” which processes the camera feed and generates the projection image, as described further hereinbelow.

As indicated in the figure, the projector may project an image that includes a highlighting pattern 122, which highlights one or more components on the board. The highlighting may provide a visible “fence” around the area at which work is to be performed, or may provide additional indications relevant for the work. For example, the highlighting may be color coded according to the type of component to be installed or tested, or may indicate a shape reflecting the type of component. Additional types of projection images provided by the system 100 are described below.

An operator working on the PCB, typically to assemble or to test the PCB, will typically select a component or region of the board on which to work. The processor then generates an appropriate projection image that “lights” a highlighting pattern on the correct area of the PCB, in order to assist the operator in locating the component or region. As described below, the component or region to be highlighted may be specified by the operator while performing tasks of assembly and/or testing. Alternatively or additionally, the specification of what to be highlighted may be preset by a stored assembly or testing plan according to which the operator works.

Also shown are input/output (I/O) ports 126 of the system, which may be, for example, USB or Ethernet ports, for receiving input and generating output as described further hereinbelow. These ports may be positioned in the optical unit as indicated, or in the projector arm or base. Alternatively or additionally the system may communicate externally by wireless means.

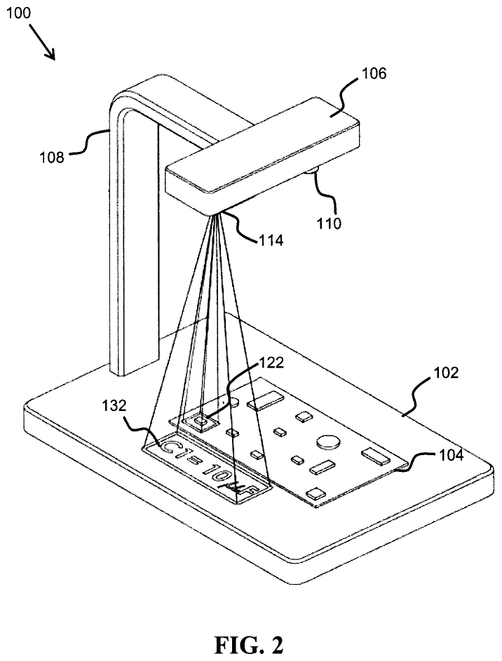

FIG. 2 is a schematic diagram of the system 100, shown projecting both the highlighting pattern 122 described above and a text message 132, in accordance with an embodiment of the present invention. As indicated, the highlighting pattern 122 is projected onto the PCB, while the text message 132 is projected onto the base, near the highlighted component. Orientation of the text can be controlled, for example to be oriented in the direction facing an operator. In further embodiments, whether to project the text onto the board itself or onto the base may be selected by the operator.

The text message 132 is generated as part of the projection image generated by the processor described above. (In the example shown, the projection imaged includes both the highlighted pattern 122 and the text message 132.) The text message in the given example shows the type of component that is to be mounted or tested at the given (highlighted) position, in this case “C1=10 μF”. In other words, the text indicates useful information to the operator about the component itself. In further embodiments, a text message may be instruction to an operator of the system, such as a step of an assembly instruction and a testing instruction. For example, a testing instruction may be an indication of a type of test to perform.

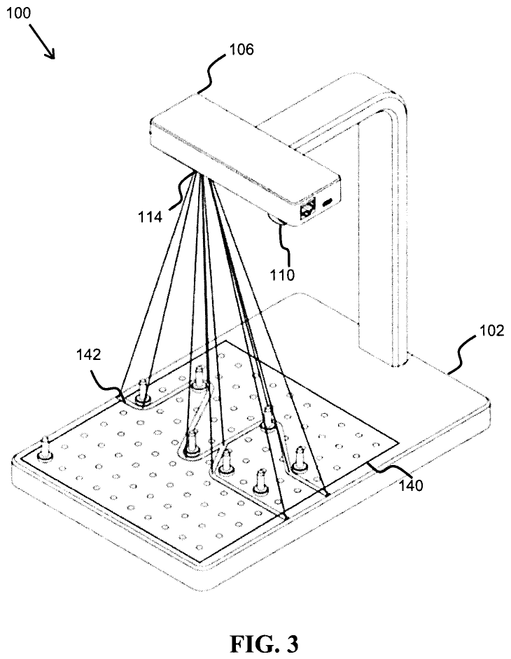

FIG. 3 is a schematic diagram of the system 100, shown indicating a cabling or wire harness path, in accordance with an embodiment of the present invention. As indicated, on a PCB 140, a path over which cabling or a wire harness is to be laid is indicated by a projected pattern 142.

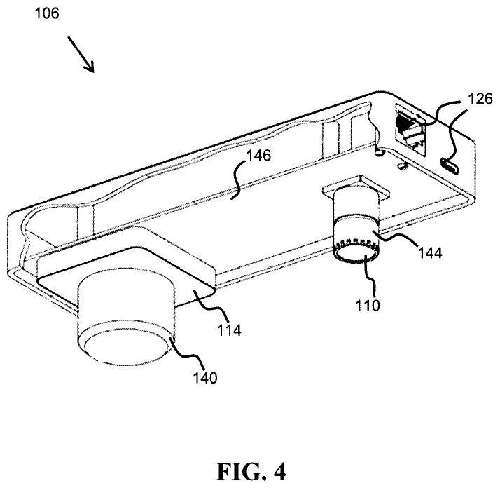

FIG. 4 is a schematic diagram of the optical unit 106, in accordance with an embodiment of the present invention. The optical unit includes the camera 110 and the projector 114. The camera may include a zoom lens 110, lens which may provide a high resolution zoomed image of a PCB region including the position of the component on the PCB. The zoom may be controlled by the processor to enhance the resolution of the image of the given position. The projector field of view may also be modified to accommodate different resolutions. In some embodiments, the camera and/or the projector also include an auto-focus range finder. The camera resolution is typically configured to be sufficient to enable the processor to distinguish components on the board, so as to determine whether or not components have been mounted. The projector may employ any known projection technology, such as Digital Light Processing (DLP), based on Digital Micromirror Device (DMD) semiconductor chips, or liquid crystal on silicon (LCoS) technology.

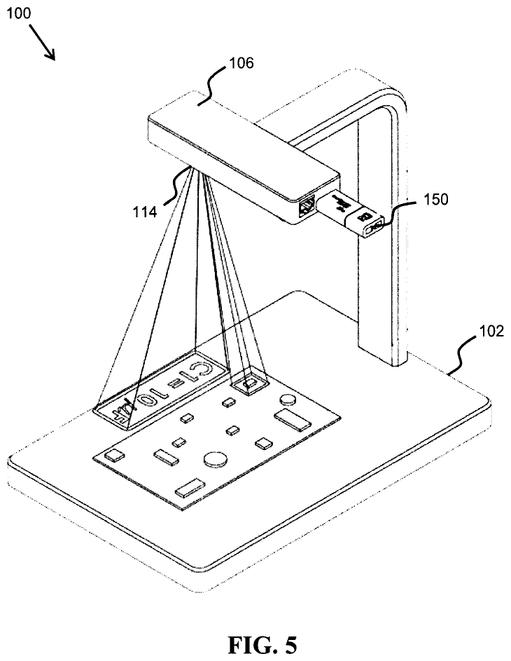

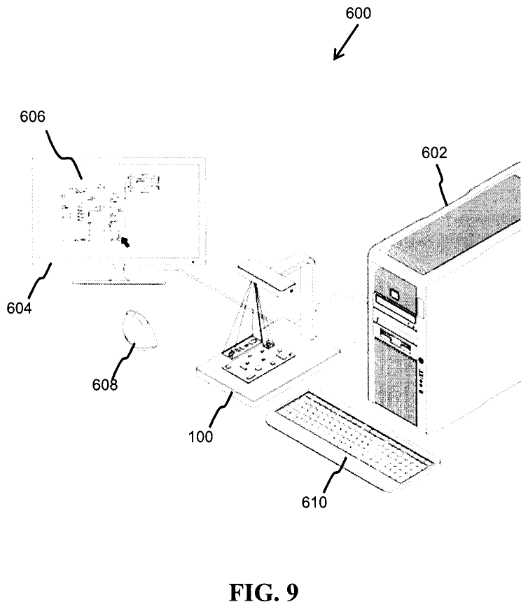

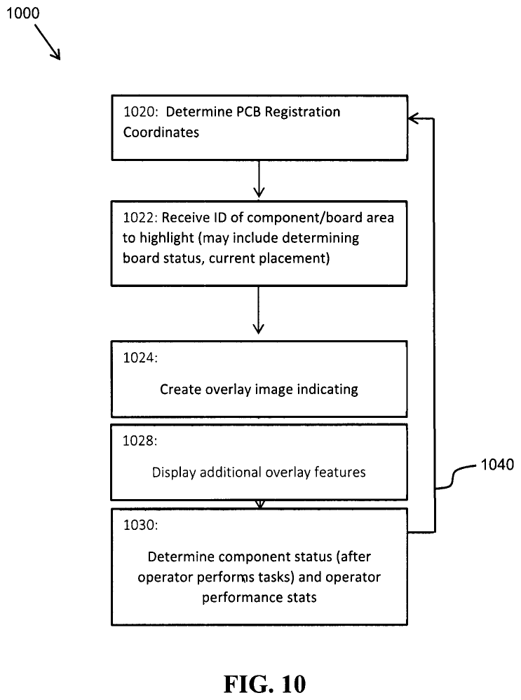

System 100 typically includes an embedded processor, which may be assembled with a control board 146 positioned in the optical unit. Processing functions are described further hereinbelow with respect to the flow chart of FIG. 10. Also shown are the I/O ports 126, described further hereinbelow with respect to FIGS. 5 and 9.

FIG. 5 is a schematic diagram of the system 100, shown receiving a memory cartridge 150, in accordance with an embodiment of the present invention. As indicated, the memory cartridge may be inserted into one of the I/O ports 126 shown above in FIG. 4. Typically, the memory cartridge provides assembly instructions and/or PCB layout and Bill of Material (BOM) data relevant for the given PCB under assembly or testing. The data provided may be used by the processor to determine positions of the board to highlight and text or instructions to display to an operator.

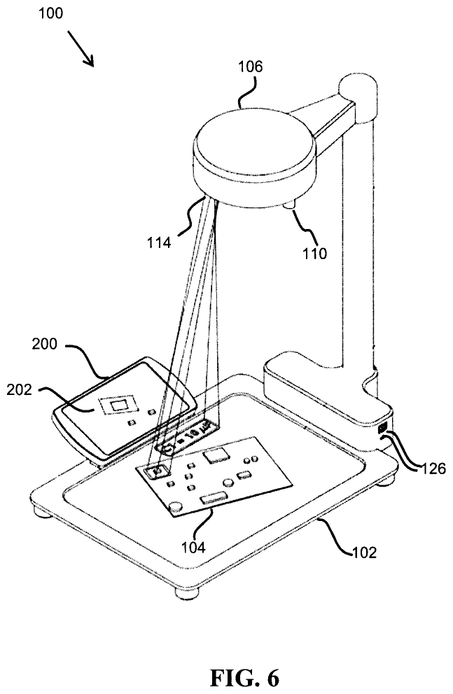

FIG. 6 is a schematic diagram of the system 100, including a magnification video display 200, in accordance with an embodiment of the present invention. As described above, the projector 114 indicates on the PCB a position of the board with highlighting, indicated where an operator is to perform work of development, assembly, or testing. Additional text may also be projected on or near the PCB. In addition, the magnification video display 200 may receive from the processor a magnified image 202 of the area at which work is being performed. That is, the image 202 displayed on magnification video display 200 may be a real-time view of the highlighted position of the PCB, which is the image, or a part of the image, captured by the camera 110. The magnification video display 200 may be detached from the system 100 or may be “base” or “side” mounted.

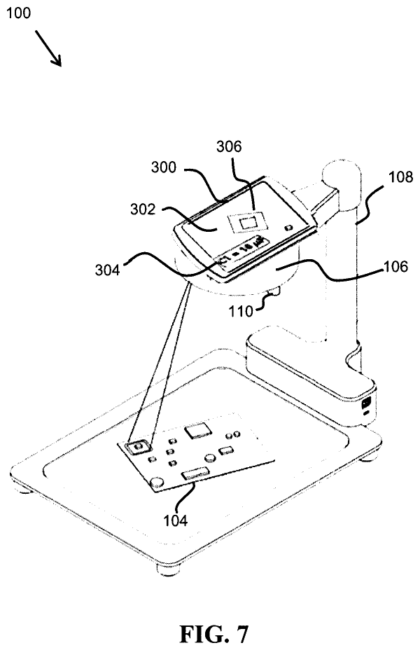

FIG. 7 is a schematic diagram of the system 100, including a top-mounted magnification video display 300, in accordance with an embodiment of the present invention. The top-mounted video display is configured as part of the optical unit 106, with a screen facing upwards, such that a magnified image 302, like the image 202, is presented to the operator. As indicated, the projector arm 108 may be shorter (i.e., the optical unit may be positioned lower) when the top-mounted magnification video display is installed, as the operator would look at both the top-mounted video display and the PCB. An additional feature of the top-mounted magnification video display 300 is that it may also display text messages 304, to the operator, such as the text messages 132 described above that may be projected onto the PCB and/or base. The feature of textual display in conjunction with a magnified image of the highlighted PCB position may also be provided with the video display 200, described above. With the magnification video displays, top-mounted or not, are employed with the system 100, the projector may be optional. That is, the magnified image 302 may include an overlay image of a highlighted pattern that indicates the position of a component to be assembled or tested. If the projector is not used, the processor merges the overlay pattern with the camera image and transmits the merged image to the magnification video display.

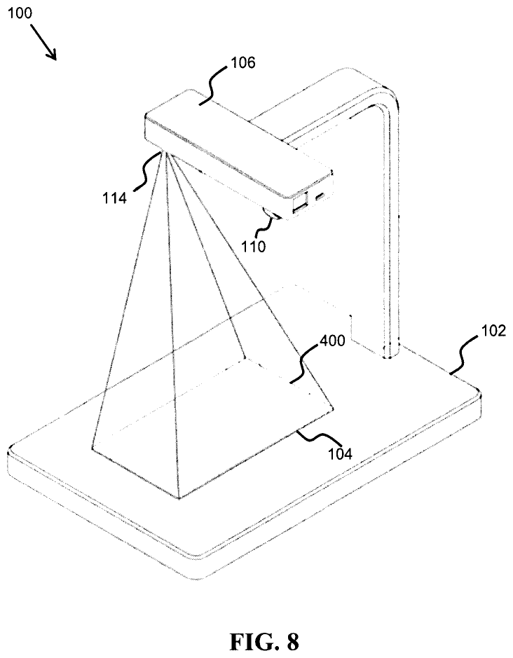

FIG. 8 is a schematic diagram of the system 100, shown indicating a PCB orientation 400, in accordance with an embodiment of the present invention. The projector may be configured to indicate a position and orientation for placing a PCB. Alternatively or additionally, the processor may receive an image of the PCB and register the position of the PCB either by finding fiduciary points printed on the PCB or by identifying other characteristics of the PCB, such as edge or component features. The processor registers the physical position of the board with a representative layout of the board that is stored in memory accessible to the processor.

FIG. 9 is a schematic diagram of an interactive system 600 for assisting in manual assembly and testing of PCBs, in accordance with an embodiment of the present invention. The system 100 described above may be connected to an external computer system 602, which may be, for example, a mainframe computer, a personal desktop computer, a laptop computer, a tablet, and a smart phone. Some or all of the processing of the system may be performed by an embedded processor as described above or by the external computer system, which may be connected to the system 100 by wireless or wired means as described above. Typically the system 600 is interactive, such that the processor provides on a workstation display 604 a view, for example, of a logical circuit schematic 606 of the PCB. This permits the operator to select (i.e., “request”) a component for testing or assembly, making the selection with interactive devices such as a mouse 608 and a keyboard 610. The workstation display may also display, for example, a PCB layout or a BOM from which the operator can interactively select components on which to work. The workstation display may also display instructions or part of the information that may be projected by the projector as described above.

FIG. 10 is a flow diagram of a process 1000 for assisting with manual assembly of a printed circuit board (PCB), in accordance with an embodiment of the present invention.

At a step 1020, a processor is provided with data with respect to a PCB to be assembled or tested. The data typically includes a board layout and bill of materials, indicating the components that are on the PCB and their position on the PCB with respect to fiduciary points or other features, such as an edge or corner of the board. The camera of the system 100 then captures a camera image of some or all of a PCB placed on the base of the system 100. This may occur automatically with the camera providing a constant video stream, such that the processor may identify placement of the PCB. The processor then compares the camera image of the PCB with a stored layout, applying either fiduciary points of the PCB or edges or other known features to generate a registration between the physical position of the PCB and a PCB layout, such that physical positions of components on the PCB, with respect to the base, can be determined.

At a step 1022, the processor may receive a PCB worklist of tasks to perform with respect to the PCB. These may be assembly instructions, such as tasks of mounting components, wiring cables, etc. Alternatively, they may instructions for a set of tests to be performed on one or more components. The processor may then correlate that worklist to a list of installed components as determined by scanning the camera image, to determine, for example, which tasks in an assembly worklist have been completed (i.e., the components are mounted) and which still need to be completed. The processor may determine that the first assembly task on the worklist that has not been completed is the task that is now to be performed. The task is associated with a position on the board at which the assembly is to be performed.

Alternatively, the processor may receive from an operator at the interactive workstation described above an indication of a component that should be tested or worked on (e.g., replaced). The indication may be made on an interactive display that shows a PCB schematic. The processor may then determine from the PCB layout, according to the component indicated by the operator, the physical location of the component to be worked on.

Once a physical location on the PCB is determined, the processor, at a step 1024, generates an overlay image to visually indicate the position on the PCB at which the task is to be performed. The overlay image may then be projected onto the PCB or may be merged with a camera image and displayed on a magnification video screen, or both.

At a step 1028, the processor may also add additional features to the overlay image to project or display, such as instructions and/or component details, such as a component value (e.g., a capacitor value).

At a step 1030, the operator may indicate that the task is done, for example by checking off an instruction listed on the interactive display. When the operator's work is being guided by a worklist, for example for an assembly project, the processor may then determine the next task that is to be performed and present it to the operator continuing iteratively, as indicated by arrow 1040. The processor may also analyze a new camera image to determine that the task has been completed (e.g., the component has been mounted). The processor may also collect statistics, such as the rate of task performance by the operator. The processor may also maintain a completion log for individual PCBs, so that if work is stopped, subsequent work may begin with knowledge of what has been completed. It may be noted that with the statistics on rate of task performance, the system may also compare operator performance over the course of hours, days, etc.

The process 1000 continues iteratively, as indicated by the arrow 1040, typically to the first step of process 1000, re-registering the PCB in case there have been any movements of the PCB on the base.

The system implementing the above described method may be an add-on, or upgrade, or a retrofit to a commercial product for PCB design and testing, such as software programs to store and process component databases and CAD drawings.

Processing elements of the system described herein may be implemented in digital electronic circuitry, or in computer hardware, firmware, software, or in combinations thereof. Such elements can be implemented as a computer program product, tangibly embodied in an information carrier, such as a non-transient, machine-readable storage device, for execution by, or to control the operation of, data processing apparatus, such as a programmable processor, computer, or deployed to be executed on multiple computers at one site or one or more across multiple sites. Memory storage for software and data may include multiple one or more memory units, including one or more types of storage media. Examples of storage media include, but are not limited to, magnetic media, optical media, and integrated circuits such as read-only memory devices (ROM) and random access memory (RAM). Network interface modules may control the sending and receiving of data packets over networks. Method steps associated with the system and process can be rearranged and/or one or more such steps can be omitted to achieve the same, or similar, results to those described herein.

It is to be understood that the embodiments described hereinabove are cited by way of example, and that the present invention is not limited to what has been particularly shown and described hereinabove.

1. A system for assisting with manual assembly of a printed circuit board (PCB) comprising:
a camera, oriented to capture a camera image of some or all of the PCB, and
a processor, including memory having instructions that when executed perform steps of: determining, according to the camera image, a registration between a physical position of the PCB and a PCB layout; receiving a PCB worklist of tasks to perform on components of the PCB; determining, according to the registration and the worklist, a position on the PCB at which a task is to be performed; and responsively generating an overlay image to visually indicate the position on the PCB at which the task is to be performed.

2. The system of claim 1, wherein the task to be performed is assembly of a component onto the PCB at the given position.

3. The system of claim 1, further comprising a projector configured to receive the overlay image and to project the overlay image visually onto the PCB.

4. The system of claim 1, further comprising a magnification video display, and wherein the processor is further configured to generate a merged image of the overlay image and the camera image and to present the merged image on the magnification video display.

5. The system of claim 4, wherein the camera image of the merged image presented on the magnification video display is a real-time, magnified image of a region of the PCB including the position of the PCB at which the task is to be performed.

6. The system of claim 4, wherein the camera is positioned in an optical unit above the PCB, and wherein the magnification video display is positioned on top of the optical unit to be viewed from above.

7. The system of claim 1, wherein the processor is further configured to identify components of the PCB in the camera image, to correlate the identified components with components in the PCB worklist to determine a component that is not present on the PCB, and responsively to determine the task to perform.

8. The system of claim 7, wherein the task to perform includes mounting the component on the PCB.

9. The system of claim 1, wherein the overlay image further includes text related to the component.

10. The system of claim 1, wherein the overlay image further includes text of an instruction to perform related to the task.

11. The system of claim 1, wherein the processor is an embedded processor positioned in one or more of a base, a projector arm, or an optical unit of the system.

12. The system of claim 1, wherein the camera comprises a zoom lens to provide a high resolution zoomed image of a PCB region including the position on the PCB at which the task is to be performed.

13. The system of claim 1, wherein the processor is further configured to record a time of completion of the task and responsively determine a statistic of an operator performance.

14. A system for assisting in manual printed circuit board (PCB) testing, comprising:
a camera, oriented to capture a camera image of some or all of the PCB;
a processor, including memory having instructions that when executed perform steps of: determining a correspondence between the camera image and a schematic of the PCB; responsively receiving a position request identifying a schematic location; responsively determining a physical position on the PCB of said schematic location; and responsively generating an overlay image to visually indicate said physical position on the PCB.

15. The system of claim 14, further comprising an interactive display unit, and wherein the processor is further configured to present a logical circuit schematic on the interactive display unit, from which an operator can select the schematic location.

16. A computer-based method assisting with manual assembly of a printed circuit board (PCB) having one or more processors and a memory, the memory comprising instructions that when executed by the one or more processor cause the processor to implement the method, comprising:
capturing with a camera a camera image of some or all of the PCB;
determining, according to the camera image, a registration between a physical position of the PCB and a PCB layout;
receiving a PCB worklist of tasks to perform on components of the PCB;
determining, according to the registration and the worklist, a position on the PCB at which a task is to be performed; and
responsively generating an overlay image to visually indicate the position on the PCB at which the task is to be performed.

17. The method of claim 16, wherein the overlay image is a highlighting pattern and wherein indicating the position on the PCB at which the task is to be performed comprises projecting the overlay image towards the PCB to highlight a component on the PCB.
